(19) United States
(12) Patent Application Publication
(10) Pub. No.: US 2025/0079220 A1
(43) Pub. Date: Mar. 6, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Satoshi KAKINOKI, Kyoto (JP); Hiroshi EBISUI, Kyoto (JP)

(21) Appl. No.: 18/949,969

(22) Filed: Nov. 15, 2024

Related U.S. Application Data
(63) Continuation of application No. 17/887,101, filed on Aug. 12, 2022.
Application No. 17/887,101 is a continuation of application No. 16/019,620, filed on Jun. 27, 2018, now abandoned.

(30) Foreign Application Priority Data
Jul. 12, 2017 (JP) 2017-136335

(51) Int. Cl. H01L 21/68; H01L 21/67; H01L 21/677; H01L 21/687

(52) U.S. Cl. CPC H01L 21/68; H01L 21/67028; H01L 21/67051; H01L 21/6715; H01L 21/6719; H01L 21/67766; H01L 21/68742; H01L 21/68764

(57) ABSTRACT

A substrate processing apparatus includes a holding unit which holds a substrate horizontally, a facing member which faces an upper surface of the substrate from above and can be engaged with the holding unit, a supporting member which supports the facing member, a raising/lowering unit in which the supporting member is raised and lowered between an upper position at which the supporting member supports the facing member in a state where the facing member is separated above from the holding unit and an engaging position which is a position below from the upper position and at which the holding unit is engaged with the facing member, and a detecting unit which is disposed at the supporting member. The detecting unit detects a position of a portion to be detected which is disposed at the facing member in relation to the detecting unit.

### CROSS REFERENCE TO RELATED APPLICATIONS

This is a Continuation of U.S. application Ser. No. 17/887,101, filed Aug. 12, 2022, which is a continuation of U.S. application Ser. No. 16/019,620, filed Jun. 27, 2018, which claims the benefit of Japanese Patent Application No. 2017-136335, filed Jul. 12, 2017, the disclosures of which are incorporated herein by reference.

### BACKGROUND OF THE INVENTION

### 1. Field of the Invention

The present invention relates to a substrate processing apparatus and a substrate processing method for processing a substrate. Substrates to be processed include, for example, semiconductor wafers, substrates for liquid crystal displays, substrates for FPDs (Flat Panel Displays) for electroluminescence displays, etc., substrates for optical disks, substrates for magnetic disks, substrates for magneto-optical disks, substrates for photomasks, ceramic substrates and substrates for solar batteries.

### 2. Description of the Related Art

In substrate processing by using a single substrate processing type substrate processing apparatus which processes one substrate at one time, a processing liquid is supplied to the substrate which is held substantially horizontal, for example, by a substrate holding portion, thereby processing a front surface of the substrate. At this time, a pattern may be oxidized by oxygen which has dissolved into the processing liquid. Therefore, it is necessary to reduce oxygen concentrations of the atmosphere in the vicinity of an upper surface of the substrate so that oxygen will not dissolve into the processing liquid. Thus, in the substrate processing apparatus described in Japanese Patent Application Publication No. 2016-162799, in order to suppress oxidation of a front surface of a substrate, a facing member that faces an upper surface of the substrate is disposed. An inert gas is supplied between the substrate and the facing member to replace the atmosphere between the facing member and the substrate with the inert gas. Thereby, an oxygen concentration in the atmosphere around the substrate is reduced to decrease a quantity of oxygen which will dissolve into a processing liquid supplied onto the substrate.

### SUMMARY OF THE INVENTION

In the substrate processing apparatus described in Japanese Patent Application Publication No. 2016-162799, in order that a substrate can be held by a substrate holding portion or the substrate can be removed from the substrate holding portion, a facing member raising/lowering mechanism for raising and lowering the facing member is disposed. In order to favorably block the atmosphere in the vicinity of a front surface of the substrate from an ambient atmosphere, it is necessary to position the facing member at a suitable height position by engaging an engaging portion disposed at the facing member with an engaging portion disposed at the substrate holding portion. However, in the substrate processing apparatus described in Japanese Patent Application Publication No. 2016-162799, a position of the facing member is not detected. Therefore, substrate processing may be executed even in a state that the engaging portion of the facing member is not favorably engaged with the engaging portion of the substrate holding portion. This may result in a possible failure of favorably processing an upper surface of the substrate.

Thus, an object of the present invention is to provide a substrate processing apparatus which is capable of judging whether a facing member is positioned at a suitable position or not in a configuration that the facing member which faces an upper surface of a substrate is raised and lowered to engage the facing member with a holding unit and also to provide a substrate processing method.

A preferred embodiment of the present invention provides a substrate processing apparatus which includes a holding unit which holds a substrate horizontally, a facing member which faces an upper surface of the substrate from above and is capable of engaging with the holding unit, a supporting member which supports the facing member, a raising/lowering unit which raises and lowers the supporting member between an upper position at which the supporting member supports the facing member in a state where the facing member is separated above from the holding unit and an engaging position which is a position lower than the upper position and at which the holding unit and the facing member are engaged with each other and a detecting unit which is disposed at the supporting member, and in which the detecting unit detects a position of a portion to be detected, which is disposed at the facing member, in relation to the detecting unit.

According to the above-described configuration, the supporting member is raised and lowered between the upper position at which the facing member is supported and the engaging position at which the facing member is engaged with the holding unit. The detecting unit which detects a position of the portion to be detected, which is disposed at the facing member, is disposed at the supporting member. Therefore, a position of the portion to be detected in relation to the detecting unit can be detected by the detecting unit in a state where the facing member is engaged with the holding unit. It is, thereby, possible to judge whether the facing member is positioned at a suitable position or not.

In a preferred embodiment of the present invention, a plurality of the detecting units are disposed at intervals in a circumferential direction around a vertical axis which passes through a central portion of the facing member. Therefore, it is possible to detect a position of the portion to be detected at a plurality of sites in relation to the detecting unit in the circumferential direction. Accordingly, it is possible to judge more accurately whether the facing member is positioned at a suitable position or not.

In a preferred embodiment of the present invention, the detecting unit optically detects a position of the portion to be detected in relation to the detecting unit, and the portion to be detected has a reflection surface which reflects light more easily compared to a part of the facing member other than the portion to be detected. Therefore, the detecting unit is able to improve the sensitivity to detect a position of the portion to be detected. Accordingly, it is possible to judge more accurately whether the facing member is positioned at a suitable position or not.

In a preferred embodiment of the present invention, the substrate processing apparatus further includes a controller which controls the raising/lowering unit. The raising/lowering unit is capable of lowering the supporting member to a lower position which is a position below from the engaging position and at which the supporting member is separated below from the facing member in a state of being engaged with the holding unit. The controller is programmed so as to execute a lowering step in which the supporting member is lowered from the upper position to the lower position by the raising/lowering unit, and a raising step in which the supporting member is raised from the lower position to the upper position by the raising/lowering unit after the lowering step.

According to the above-described configuration, the supporting member supports the facing member when being positioned at the upper position and is separated below from the facing member when being positioned at the lower position. Therefore, it is possible to transfer the facing member from the supporting member to the holding unit when the supporting member passes through the engaging position during the lowering step. Then, when the supporting member passes through the engaging position during the raising step, the supporting member is able to receive the facing member from the holding unit. Accordingly, it is possible to judge whether the facing member is positioned at a suitable position or not in a configuration that the facing member is transferred between the supporting member and the holding unit.

In a preferred embodiment of the present invention, the detecting unit is controlled by the controller. The detecting unit includes a distance measurement sensor which measures a distance between the detecting unit and the portion to be detected, thereby detecting a position of the portion to be detected in relation to the detecting unit. The controller is programmed so as to execute a first distance measurement step in which, before start of the lowering step, a distance between the detecting unit and the portion to be detected is measured by the detecting unit in a state that the supporting member is positioned at the upper position, and a second distance measurement step in which, after completion of the lowering step and before start of the raising step, a distance between the detecting unit and the portion to be detected is measured by the detecting unit in a state that the supporting member is positioned at the lower position.

A distance between the detecting unit and the portion to be detected is different between a state where the supporting member is positioned at the upper position and a state where the supporting member is positioned at the lower position. Accordingly, it is possible to judge whether the facing member is normally engaged with the holding unit or not, based on whether the amount of change in distance between the detecting unit and the portion to be detected is appropriate. It is, thereby, possible to judge more accurately whether the facing member is positioned at a suitable position or not.

In a preferred embodiment of the present invention, the portion to be detected is disposed such that a height from the facing member to a tip end of the portion to be detected is adjustable. Therefore, it is possible to adjust a height of the portion to be detected according to a measurement range of the distance measurement sensor. Accordingly, it is possible to judge more accurately whether the facing member is positioned at a suitable position or not.

In a preferred embodiment of the present invention, the distance measurement sensor includes an upper position sensor which measures a distance between the detecting unit and the portion to be detected when the supporting member is positioned at the upper position, and a lower position sensor which measures a distance between the detecting unit and the portion to be detected when the supporting member is positioned at the lower position.

Therefore, it is possible to use a sensor, having a measurement range appropriate for measuring a distance between the detecting unit and the portion to be detected when the supporting member is positioned at the upper position, as the upper position sensor. It is also possible to use a sensor, having a measurement range appropriate for measuring a distance between the detecting unit and the portion to be detected when the supporting member is positioned at the lower position, as the lower position sensor. Accordingly, it is suppressed that a distance in which the supporting member is separated from the facing member is restricted due to a measurement range of a sensor. Also, it is suppressed that detection accuracy is decreased due to a distance between the detecting unit and the portion to be detected. It is, thereby, possible to judge more accurately whether the facing member is positioned at a suitable position or not.

In a preferred embodiment of the present invention, the controller is programmed so as to execute, in the lowering step, a high-speed lowering step in which the supporting member is lowered at a relatively high speed from the upper position to a predetermined intermediate position between the upper position and the engaging position, and a low-speed lowering step in which the supporting member is lowered at a relatively low speed from the predetermined intermediate position between the upper position and the engaging position to the lower position.

Here, in the lowering step and the raising step, it is conceivable that the supporting member is lowered or raised at a fixed speed without any change in speed during each step. If lowering speed or raising speed of the supporting member is increased in a case where the supporting member is lowered or raised at a fixed speed, the number of substrates which can be processed per unit time (throughput) is improved but an impact which the facing member receives is increased. Thereby, the facing member is deformed or misaligned, so that the facing member and the holding unit may not engage well. In contrast, if lowering speed or raising speed of the supporting member is decreased in a case where the supporting member is lowered or raised at a fixed speed, an impact which the facing member receives is decreased but the throughput may be reduced.

Thus, the substrate processing apparatus is configured such that the supporting member can be lowered at a relatively high speed from the upper position to the intermediate position and the supporting member is lowered at a relatively low speed from the intermediate position to the lower position, that is, the substrate processing apparatus is configured such that the supporting member can be lowered at a relatively high speed at a position separated above from the engaging position and the supporting member is lowered at a relatively low speed when the holding unit is engaged with the facing member, by which the lowering step can be completed in a short time. An impact which the facing member receives from the holding unit can also be reduced when the facing member is engaged with the holding unit. It is, thereby, possible to suppress the deformation of the facing member and the positional deviation of the facing member due to the impact while improving the throughput. In the low-speed lowering step, the supporting member may be lowered at a fixed speed.

In a preferred embodiment of the present invention, the controller is programmed so as to execute, in the raising step, a low-speed raising step in which the supporting member is raised at a relatively low speed from the lower position to a predetermined intermediate position between the upper position and the engaging position, and a high-speed raising step in which the supporting member is raised at a relatively high speed from the predetermined intermediate position between the upper position and the engaging position to the upper position.

Therefore, when the facing member is transferred from the holding unit to the supporting member, the supporting member is raised at a relatively low speed, and the supporting member is raised at a relatively high speed at a position separated above from the engaging position. Accordingly, it is possible to complete the raising step in a short time and also to reduce an impact which the facing member receives from the holding unit when the facing member is separated from the holding unit. It is, thereby, possible to suppress the deformation of the facing member and the positional deviation of the facing member due to the impact while improving the throughput. In the low-speed raising step, the supporting member may be raised at a fixed speed.

In a preferred embodiment of the present invention, the holding unit and the facing member are engaged by a magnetic force. The magnetic force acts on the facing member when the supporting member is positioned between the predetermined intermediate position and the engaging position. Therefore, the facing member and the holding unit can be easily engaged each other by the magnetic force without using a complicated mechanism.

Here, when the facing member is deformed, the facing member is locally changed in height position. Therefore, the facing member may not be arranged at a suitable position even when the supporting member has reached the engaging position. Deformation of the facing member will result in a change in width between the detecting portions disposed on an upper surface of the facing member.

In a preferred embodiment of the present invention, the substrate processing apparatus further includes a rotating unit which is controlled by the controller and rotates the holding unit around a predetermined rotation axis along a vertical direction. A plurality of the portions to be detected are disposed on the upper surface of the facing member at intervals in a rotation direction around the rotation axis. The controller is programmed so as to execute a rotating step in which the facing member is rotated integrally with the holding unit by the rotating unit in a state where the supporting member is positioned at the lower position, and a monitoring step in which, in parallel with the rotating step, positions of the plurality of portions to be detected in relation to the detecting unit are detected by the detecting unit, thereby monitoring a distance between the portions to be detected.

According to the above-described configuration, in the rotating step, the facing member is engaged with the holding unit and the supporting member is separated below from the facing member, thereby the facing member is rotated integrally with the holding unit. Therefore, in the rotating step, the facing member and the supporting member rotate relative to each other. By detecting positions of the plurality of portions to be detected with respect to the detecting unit during the relative rotation of the facing member with the supporting member, it is possible to detect which position (angle) the portion to be detected is positioned in the rotation direction of the facing member. A distance between the portions to be detected can be monitored on the basis of a result thereof. It is possible to detect deformation of the facing member which has occurred during the rotation by continuing the monitoring in the rotating step. It is also possible to judge whether the facing member is positioned at a suitable position or not by detecting the deformation during the rotation.

In a preferred embodiment of the present invention, the facing member is attachable to and detachable from the supporting member when being positioned at a predetermined relative rotation position in relation to the supporting member. The controller is programmed so as to execute a rotational position adjusting step in which, after completion of the rotating step and before start of the raising step, the holding unit is adjusted for a position in the rotation direction by the rotating unit such that the facing member is not positioned at the predetermined relative rotation position. Therefore, it is possible to raise the supporting member together with the facing member after completion of the rotating step in such a configuration that the facing member is attachable to and detachable from the supporting member.

In a preferred embodiment of the present invention, the detecting unit is capable of measuring a distance between the detecting unit and the upper surface of the facing member, and the controller is programmed so as to execute, in the monitoring step, a step in which a distance between the detecting unit and the upper surface of the facing member is monitored. Thereby, it is possible to detect undulation (deformation) of the upper surface of the facing member. It is, therefore, possible to detect more easily deformation of the facing member which has occurred during the rotation.

In a preferred embodiment of the present invention, the plurality of portions to be detected include a first protrusion and a second protrusion which are different from each other in height from the upper surface of the facing member. A height from the upper surface of the facing member to the first protrusion and a height from the upper surface of the facing member to the second protrusion are different from each other. Therefore, a height position of the first protrusion with respect to the detecting unit and a height position of the second protrusion with respect to the detecting unit are different from each other. Thus, the detecting unit is able to easily identify the first protrusion and the second protrusion. It is, thereby, possible to know more accurately a position of a deformed part of the facing member in the rotation direction.

A preferred embodiment of the present invention provides a substrate processing method which includes a substrate holding step in which a substrate is held horizontally by a holding unit, a supporting step in which a facing member which faces an upper surface of the substrate from above is supported by a supporting member, a first distance measurement step in which a distance between a portion to be measured which is disposed at the facing member and a distance measurement sensor which is disposed at the supporting member is measured by the distance measurement sensor in a state where the supporting member is positioned at an upper position at which the supporting member supports the facing member such that the facing member is separated above from an engaging member disposed at the holding unit, a lowering step in which the supporting member is lowered from the upper position to a lower position at which the supporting member is separated below from the facing member in a state of being engaged with the holding unit by way of an engaging position at which the holding unit and the facing member are engaged with each other, and a second distance measurement step in which, after completion of the lowering step, a distance between the portion to be measured and the distance measurement sensor is measured by the distance measurement sensor in a state where the supporting member is positioned at the lower position.

According to the above-described method, a distance between the detecting unit and the portion to be detected is different between a state before start of the lowering step (a state that the supporting member is positioned at the upper position) and a state after completion of the lowering step (a state that the supporting member is positioned at the lower position). Accordingly, it is possible to judge whether the facing member and the holding unit have been normally engaged with each other or not, based on whether the amount of change in distance between the detecting unit and the portion to be detected is appropriate. It is, thereby, possible to judge whether the facing member is positioned at a suitable position or not.

In a preferred embodiment of the present invention, the lowering step includes a high-speed lowering step in which the supporting member is lowered at a relatively high speed from the upper position to a predetermined intermediate position between the upper position and the engaging position, and a low-speed lowering step in which the supporting member is lowered at a relatively low speed from the predetermined intermediate position between the upper position and the engaging position to the lower position.

Therefore, at a position separated above from the engaging position, the supporting member is lowered at a relatively high speed, and when the holding unit and the facing member are engaged with each other, the supporting member is lowered at a relatively low speed. Accordingly, it is possible to complete the lowering step in a short time and also to reduce an impact which the facing member receives from the holding unit when the facing member and the holding unit are engaged with each other. It is, thereby, possible to suppress the deformation of the facing member and the positional deviation of the facing member due to the impact while improving the throughput. In the low-speed lowering step, the supporting member may be lowered at a fixed speed.

In a preferred embodiment of the present invention, the substrate processing method further includes a raising step in which the supporting member is raised from the lower position to the upper position. The raising step includes a low-speed raising step in which the supporting member is raised at a relatively low speed from the lower position to a predetermined intermediate position between the upper position and the engaging position, and a high-speed raising step in which the supporting member is raised at a relatively high speed from the predetermined intermediate position between the upper position and the engaging position to the upper position.

When the facing member is transferred from the holding unit to the supporting member, the supporting member is raised at a relatively low speed, and at a position separated above from the engaging position, the supporting member is raised at a relatively high speed. Accordingly, it is possible to complete the raising step in a short time and also to reduce an impact which the facing member receives from the holding unit when the facing member is separated from the holding unit. It is, thereby possible to suppress the deformation of the facing member and the positional deviation of the facing member due to the impact while improving the throughput. In the low-speed raising step, the supporting member may be raised at a fixed speed.

In a preferred embodiment of the present invention, the holding unit and the facing member are engaged each other by a magnetic force. The magnetic force acts on the facing member when the supporting member is positioned between the predetermined intermediate position and the engaging position. Therefore, the facing member and the holding unit can be easily engaged each other by the magnetic force without using a complicated mechanism.

A preferred embodiment of the present invention provides a substrate processing method which includes a substrate holding step in which a substrate is held horizontally by a holding unit, a supporting step in which a facing member which faces an upper surface of the substrate is supported by a supporting member, a lowering step in which the supporting member is lowered from an upper position at which the supporting member supports the facing member such that the facing member is separated above from the holding unit to a lower position which is a position lower than an engaging position at which the holding unit and the facing member are engaged with each other and at which the supporting member is separated below from the facing member in a state of being engaged with the holding unit, a rotating step in which when the supporting member is positioned at the lower position, the holding unit is rotated in a rotation direction around a predetermined rotation axis along a vertical direction, and a monitoring step which is executed in parallel with the rotating step and in which positions of a plurality of portions to be detected which are disposed at intervals in the rotation direction on an upper surface of the facing member in relation to a detecting unit disposed at the supporting member are detected by the detecting unit, thereby monitoring a distance between the portions to be detected.

According to the above-described method, in the rotating step, the facing member and the holding unit are engaged, and the supporting member is separated below from the facing member, so that the facing member is rotated integrally with the holding unit. Therefore, in the rotating step, the facing member and the supporting member rotate relative to each other. By detecting positions of the plurality of portions to be detected with respect to the detecting unit during the relative rotation of the facing member and the supporting member, it is possible to detect which position (angle) the portion to be detected is positioned in a rotation direction of the facing member. On the basis of a result thereof, a distance between the portions to be detected can be monitored. It is possible to detect deformation of the facing member which has occurred during the rotation by continuing the monitoring in the rotating step. It is possible to judge whether the facing member is positioned at a suitable position or not by detecting the deformation during the rotation.

In a preferred embodiment of the present invention, the substrate processing method further includes a rotational position adjusting step in which, after completion of the rotating step, the holding unit is adjusted for a position in the rotation direction such that the facing member is not positioned at a predetermined relative rotation position at which the facing member is attachable to and detachable from the supporting member, and a raising step in which, after completion of the rotational position adjusting step, the supporting member is raised from the lower position to the upper position. It is, thereby, possible to raise the supporting member together with the facing member after completion of the rotating step in such a configuration that the facing member can be attached to and detached from the supporting member.

In a preferred embodiment of the present invention, the monitoring step includes a step in which a distance between the detecting unit and the upper surface of the facing member is monitored. It is, thereby, possible to detect undulation of the upper surface of the facing member. Therefore, it is possible to detect more easily deformation of the facing member which has occurred during the rotation.

The above and yet other objects, features and effects of the present invention shall be made clear by the following description of the preferred embodiments in reference to the accompanying drawings.

### BRIEF DESCRIPTION OF THE DRAWINGS

FIG. 1 is a schematic plan view for describing a layout of an interior of a substrate processing apparatus according to a preferred embodiment of the present invention.

FIG. 2 is a schematic view of a processing unit which is provided at the substrate processing apparatus.

FIG. 3A is a perspective view of a facing member which is provided at the processing unit.

FIG. 3B is a perspective view in which the facing member is viewed at an angle different from that of FIG. 3A.

FIG. 4A is a sectional view which is taken along line IV to IV in FIG. 2, showing a state where a relative rotation position of the facing member is a supporting position.

FIG. 4B is a sectional view which is taken along the line of IV to IV in FIG. 2, showing a state where the relative rotation position of the facing member is a removal position.

FIG. 5 is a sectional view which shows a vicinity of an engaging portion disposed at the facing member.

FIG. 6 is a block diagram for describing an electrical configuration of major portions in the substrate processing apparatus.

FIG. 7 is a flowchart for describing one example of substrate processing by the substrate processing apparatus.

FIG. 8A to FIG. 8F are each an illustrative sectional view for describing the substrate processing.

FIG. 9A is a graph which shows a relationship between a height position of the facing member and a lowering speed of the facing member in a lowering step of the substrate processing.

FIG. 9B is a graph which shows a relationship between a height position of the facing member and a raising speed of the facing member in a raising step of the substrate processing.

FIG. 10 is a graph which shows a relationship between a rotation angle of the facing member during rotation and a distance from the facing member to a measurement target.

FIG. 11 is a graph which shows a relationship between a rotation angle of the facing member during rotation and a distance from a measurement unit to a measurement target.

### DETAILED DESCRIPTION OF THE PREFERRED EMBODIMENTS

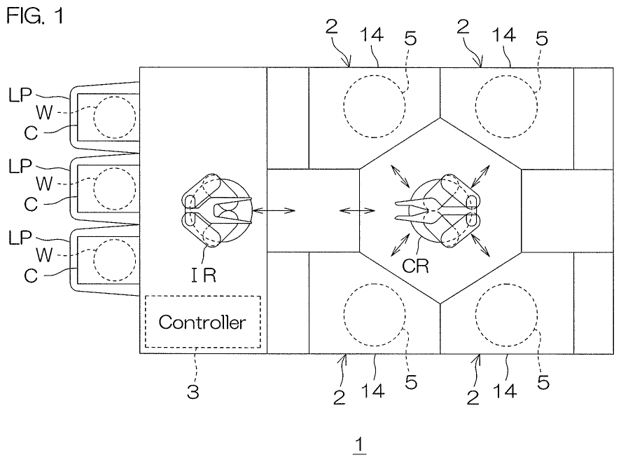

FIG. 1 is an illustrative plan view for describing a layout of an interior of a substrate processing apparatus 1 according to a preferred embodiment of the present invention.

The substrate processing apparatus 1 is a single substrate processing type apparatus which processes one substrate W such as a silicon wafer one at a time. In the present preferred embodiment, the substrate W is a disk-shaped substrate. The substrate processing apparatus 1 includes a plurality of processing units 2, each of which processes the substrate W using a processing liquid such as a chemical liquid and a rinse liquid, load ports LP on each of which is placed a carrier C housing a plurality of substrates W to be processed by the processing unit 2, transfer robots IR and CR which transfer a substrate W between the load port LP and the processing unit 2, and a controller 3 which controls the substrate processing apparatus 1. The transfer robot IR transfers a substrate W between the carrier C and the transfer robot CR. The transfer robot CR transfers a substrate W between the transfer robot IR and the processing unit 2. The plurality of processing units 2 are, for example, similar in configuration.

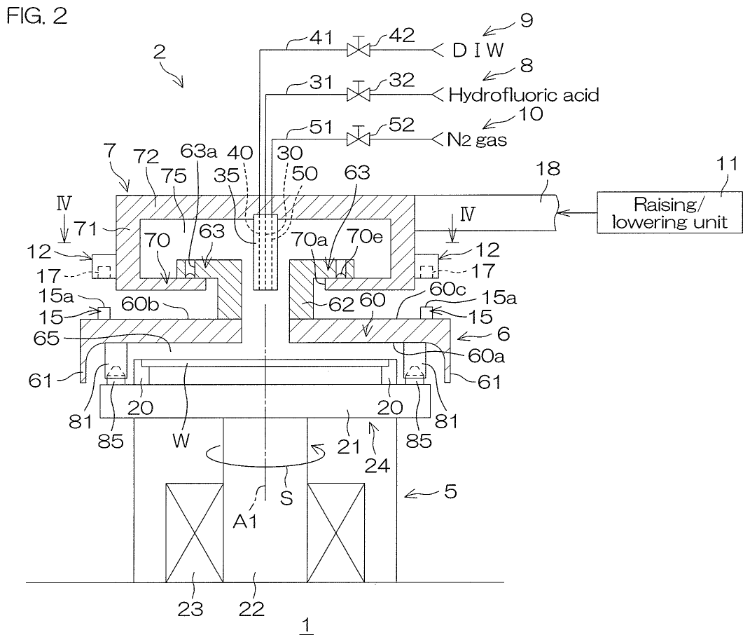

FIG. 2 is a schematic view for describing a configuration example of the processing unit 2.

The processing unit 2 includes a spin chuck 5, a facing member 6, a supporting member 7, a chemical liquid supplying unit 8, a rinse liquid supplying unit 9, a gas supplying unit 10, a raising/lowering unit 11, a pair of detecting units 12, and a chamber 14 (refer to FIG. 1).

The spin chuck 5 rotates a single substrate W around a vertical rotation axis A1 which passes through a central portion of the substrate W while holding the substrate W in a horizontal orientation. The spin chuck 5 is housed inside the chamber 14. An inlet/outlet (not shown) for carrying a substrate W in the chamber 14 and carrying out the substrate W from the interior of the chamber 14 is formed in the chamber 14. The chamber 14 is provided with a shutter unit (not shown) which opens and closes the inlet/outlet.

The spin chuck 5 includes a holding unit 24, a rotating shaft 22 and an electric motor 23. The holding unit 24 holds a substrate W horizontally. The holding unit 24 includes a spin base 21 and a plurality of chuck pins 20. The spin base 21 has a disk shape along a horizontal direction. The plurality of chuck pins 20 are arranged at intervals in a circumferential direction on an upper surface of the spin base 21. The rotating shaft 22 is coupled to a lower surface center of the spin base 21. The rotating shaft 22 extends along the rotation axis A1 in a vertical direction. The electric motor 23 applies a rotational force to the rotating shaft 22. The rotating shaft 22 is rotated by the electric motor 23, thereby rotating the spin base 21 of the holding unit 24. Thus, a substrate W is rotated in a rotation direction S around the rotation axis A1. The electric motor 23 is included in a rotating unit which rotates a substrate W around the rotation axis A1.

The chemical liquid supplying unit 8 includes a chemical liquid nozzle 30 which supplies a chemical liquid to an upper surface of the substrate W, a chemical liquid supplying pipe 31 which is coupled to the chemical liquid nozzle 30, and a chemical liquid valve 32 which is interposed in the chemical liquid supplying pipe 31. A chemical liquid such as hydrofluoric acid (hydrogen fluoride water: HF) is supplied from a chemical liquid supplying source to the chemical liquid supplying pipe 31.

The chemical liquid is not limited to hydrofluoric acid. The chemical liquid may be a liquid which includes at least any one of sulfuric acid, acetic acid, nitric acid, hydrochloric acid, hydrofluoric acid, buffered hydrofluoric acid (BHF), diluted hydrofluoric acid (DHF), ammonia water, hydrogen peroxide water, an organic acid (for example, citric acid, oxalic acid, etc.), an organic alkali (for example, TMAH: tetramethylammonium hydroxide, etc.), a surfactant and a corrosion inhibitor. Examples of the chemical liquid in which these are mixed with them include SPM (sulfuric acid/hydrogen peroxide mixture), SC1 (ammonia/hydrogen peroxide mixture) and SC2 (hydrochloric acid/hydrogen peroxide mixture).

The rinse liquid supplying unit 9 includes a rinse liquid nozzle 40 which supplies a rinse liquid to an upper surface of a substrate W, a rinse liquid supplying pipe 41 which is coupled to the rinse liquid nozzle 40, and a rinse liquid valve 42 which is interposed in the rinse liquid supplying pipe 41. A rinse liquid such as DIW is supplied from a rinse liquid supplying source to the rinse liquid supplying pipe 41.

The rinse liquid is not limited only to DIW. The rinse liquid may be carbonated water, electrolyzed ion water, ozone water, ammonia water, aqueous hydrochloric acid solution of dilute concentration (of, for example, approximately 10 ppm to 100 ppm), or reduced water (hydrogen water), etc. The rinse liquid contains water. The chemical liquid supplying unit 8 and the rinse liquid supplying unit 9 are included in the processing liquid supplying unit which supplies a processing liquid to the upper surface of the substrate W.

The gas supplying unit 10 includes a gas nozzle 50 which supplies a gas such as nitrogen gas to the upper surface of the substrate W, a gas supplying pipe 51 which is coupled to the gas nozzle 50, and a gas valve 52 which is interposed in the gas supplying pipe 51 to open and close a flow passage of the gas. A gas such as nitrogen gas is supplied from a gas supplying source to the gas supplying pipe 51.

A gas which is supplied from a gas supplying source to the gas supplying pipe 51 is preferably an inert gas such as nitrogen gas. The inert gas is not limited to nitrogen gas but may include any gas which is inert to the upper surface of the substrate W and a pattern. The inert gas includes, for example, a rare gas such as argon in addition to nitrogen gas.

In the present preferred embodiment, the chemical liquid nozzle 30, the rinse liquid nozzle 40 and the gas nozzle 50 are housed commonly in a nozzle housing member 35. A lower end portion of the nozzle housing member 35 faces a central region on the upper surface of the substrate W. The central region on the upper surface of the substrate W is a region which includes a rotation center of the substrate W.

The facing member 6 faces the upper surface of the substrate W from above. The facing member 6 blocks the atmosphere inside a space 65 between the facing member 6 and the upper surface of the substrate W from an ambient atmosphere. The facing member 6 is also referred to as a blocking member. The facing member 6 and the holding unit 24 can be engaged with each other by magnetic force. The facing member 6 can be rotated integrally with the holding unit 24 in a state of being engaged with the holding unit 24.

The supporting member 7 suspends and supports the facing member 6 from below. The facing member 6 and the supporting member 7 are configured to be able to come into and out of contact with each other. The raising/lowering unit 11 raises and lowers a supporting arm 18 mounted on the supporting member 7, thereby raising and lowering the supporting member 7. The raising/lowering unit 11 includes, for example, a ball screw mechanism (not shown) and an electric motor (not shown) that applies a driving force to the ball screw mechanism.

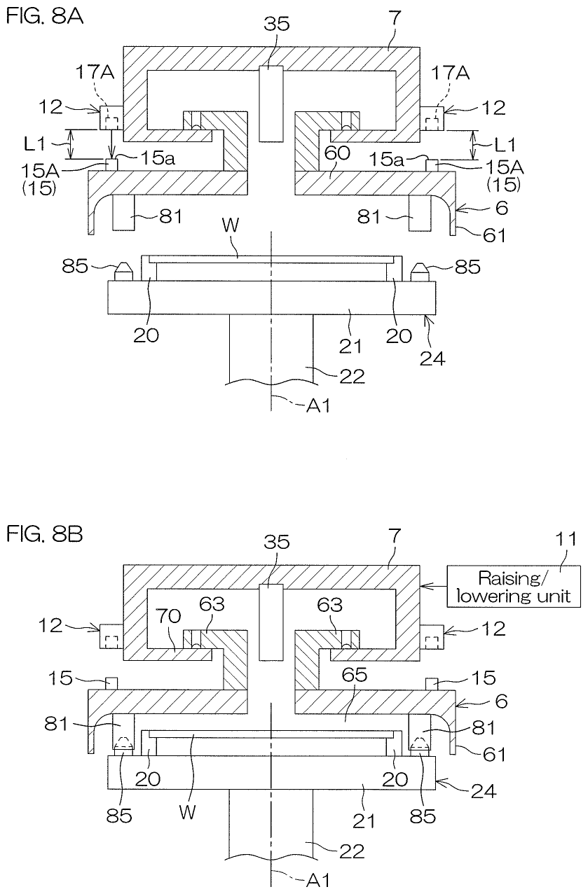

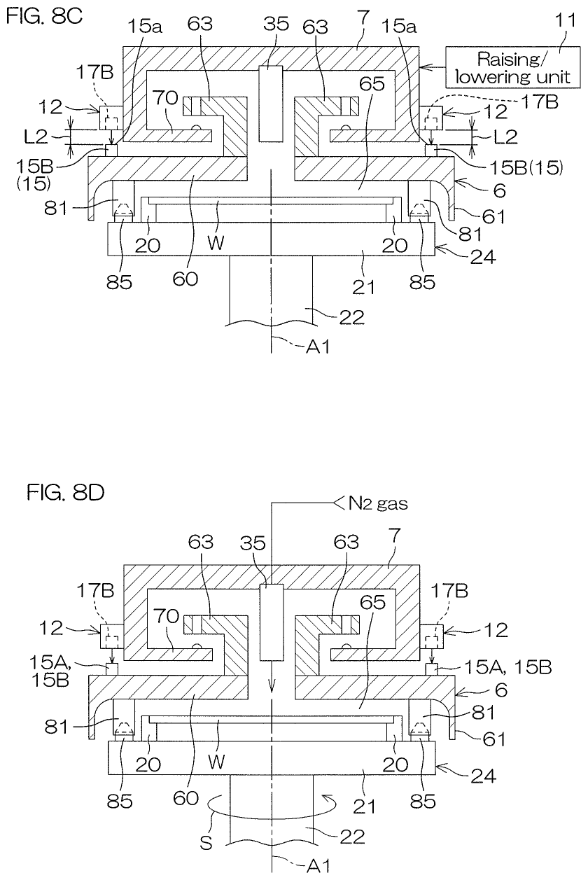

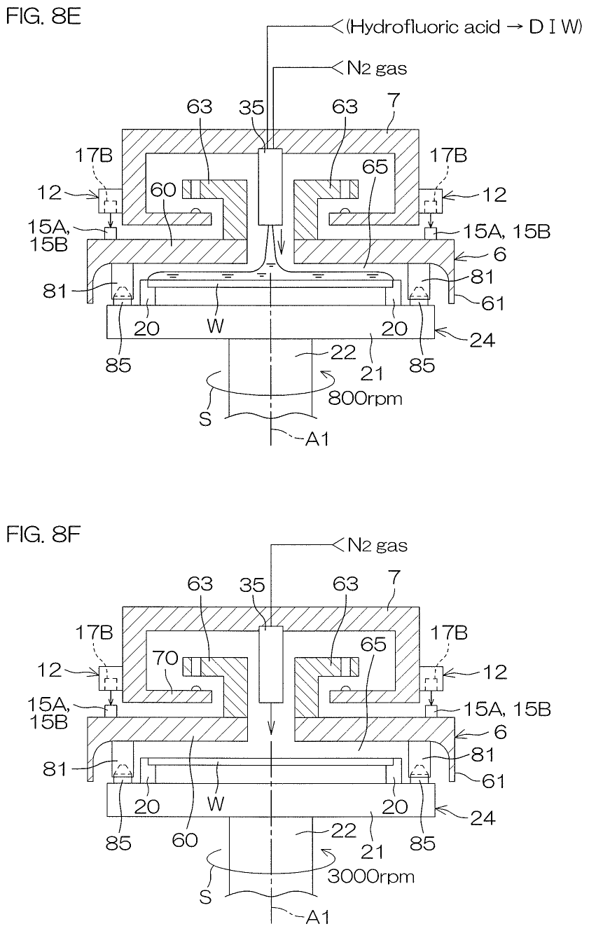

The raising/lowering unit 11 is able to position the supporting member 7 at a predetermined height position between an upper position (a position of the supporting member 7 shown in FIG. 8A which will be described later) and a lower position (a position of the supporting member 7 shown in FIG. 8C which will be described later). The lower position is a position at which the supporting member 7 comes closest to an upper surface of the spin base 21 of the holding unit 24 in a movable range. The upper position is a position at which the supporting member 7 is separated most from the upper surface of the spin base 21 of the holding unit 24 in a movable range.

The supporting member 7 suspends and supports the facing member 6 in a state of being positioned at the upper position. In this state, the facing member 6 is separated above from the holding unit 24. The supporting member 7 is raised and lowered by the raising/lowering unit 11, thereby passing through an engaging position (a position of the supporting member 7 shown in FIG. 8B which will be described later) between the upper position and the lower position. The engaging position is a height position of the supporting member 7 when the facing member 6 is supported from below by the supporting member 7 and also the facing member 6 and the holding unit 24 are engaged with each other. The supporting member 7 is separated below from the facing member 6, which is in a state of being engaged with the holding unit 24, in a state of being positioned at the lower position.

When the supporting member 7 is raised and lowered between the upper position and the engaging position, the facing member 6 is raised and lowered integrally with the supporting member 7. The supporting member 7 is separated below from the facing member 6 when being positioned between the engaging position and the lower position. The facing member 6 is kept in a state of being engaged with the holding unit 24 when the supporting member 7 is positioned between the engaging position and the lower position.

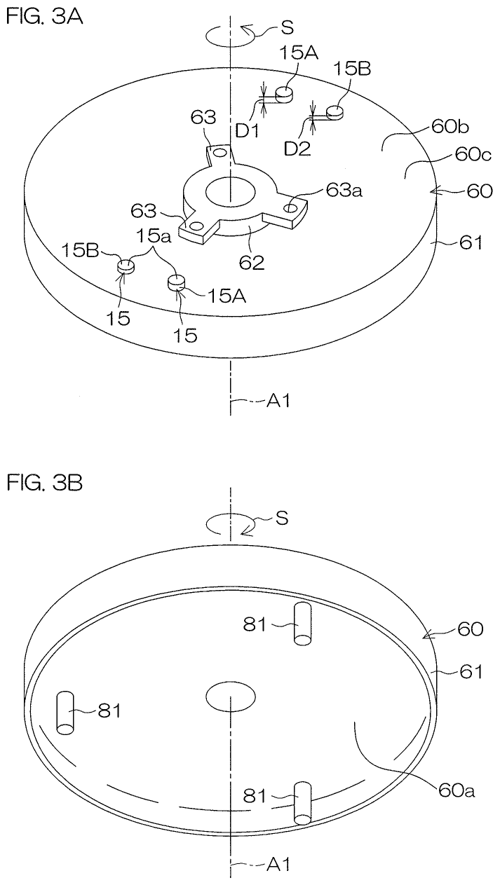

FIG. 3A is a perspective view of the facing member 6. FIG. 3B is a perspective view when the facing member 6 is viewed at an angle different from that of FIG. 3A.

With reference to FIG. 2, FIG. 3A and FIG. 3B, the facing member 6 is formed substantially in a circular shape in a plan view. The rotation axis A1 is also a vertical axis which passes through a central portion of the facing member 6. The rotation direction S is also a circumferential direction around the vertical axis which passes through the central portion of the facing member 6. The facing member 6 includes a facing portion 60, an annular portion 61, a tubular portion 62 and a plurality of flange portions 63. The facing portion 60 faces the upper surface of the substrate W from above. The facing portion 60 is formed in a disk shape. The facing portion 60 is arranged substantially horizontally above from the spin chuck 5. The facing portion 60 has a facing surface 60a which faces the upper surface of the substrate W. The facing surface 60a is also a lower surface of the facing portion 60. The annular portion 61 surrounds the substrate W in a plan view. The annular portion 61 extends downward from a peripheral edge portion of the facing portion 60. An inner peripheral surface of the annular portion 61 is curved so as to move outward in a rotation radial direction as it goes downward. An outer peripheral surface of the annular portion 61 extends along a vertical direction.

The tubular portion 62 is fixed to an upper surface 60b of the facing portion 60. The plurality of flange portions 63 are arranged at an upper end of the tubular portion 62 and kept at intervals from each other in a circumferential direction (rotation direction S) of the tubular portion 62. Each of the flange portions 63 extends horizontally from the upper end of the tubular portion 62.

The plurality of portions to be detected 15 (detection target portions) are disposed on the upper surface 60b of the facing portion 60. The upper surface 60b of the facing portion 60 is also an upper surface of the facing member 6. Each of the portions to be detected 15 is a plurality of protrusions 15A, 15B protruding above from the upper surface 60b of the facing portion 60.

The plurality of protrusions 15A, 15B include a first protrusion 15A and a second protrusion 15B which are different from each other in height from the upper surface 60b of the facing portion 60. Specifically, a height from the upper surface 60b of the facing portion 60 to an upper end of the first protrusion 15A (first height D1) is higher than a height from the upper surface 60b of the facing portion 60 to an upper end of the second protrusion 15B (second height D2). Each of the first protrusion 15A and the second protrusion 15B is, for example, a screw which is screwed into a screw hole 60d formed on the upper surface 60b of the facing portion 60 (refer to FIG. 5 which will be described later). Therefore, the first height D1 and the second height D2 can be adjusted whenever necessary.

A pair of the first protrusions 15A are disposed, and a pair of the second protrusions 15B are disposed. A pair which is configured with the first protrusion 15A and the second protrusion 15B are arranged so as to be point-symmetrical at the center of the rotation axis A1 in a plan view.

A part at which the plurality of protrusions 15A, 15B are not disposed on the upper surface 60b of the facing portion 60 is called a flat portion 60c. Each of the upper surfaces 15a of the first protrusion 15A and the second protrusion 15B is a reflection surface which will reflect light more easily compared to a part where the protrusions 15A, 15B are not disposed at the facing member 6. Further, unlike the present preferred embodiment, the entire upper surface 60b of the facing portion 60 may be a reflection surface which will reflect light more easily than a part of the facing portion 60 other than the upper surface 60b.

With reference to FIG. 2, the supporting member 7 has a space 75 which houses an upper end portion of the tubular portion 62 and the flange portion 63. The supporting member 7 includes a facing member supporting portion 70 which supports the facing member 6, a detecting unit supporting portion 71 which supports a pair of detecting units 12, and a nozzle supporting portion 72 which supports the nozzle housing member 35. The space 75 is divided by the facing member supporting portion 70, the detecting unit supporting portion 71 and the nozzle supporting portion 72. The facing member supporting portion 70 constitutes a lower wall of the supporting member 7. The nozzle supporting portion 72 constitutes an upper wall of the supporting member 7. The detecting unit supporting portion 71 constitutes a side wall of the supporting member 7. The nozzle housing member 35 is mounted substantially at the center of the nozzle supporting portion 72. A leading end of the nozzle housing member 35 is positioned below from the nozzle supporting portion 72.

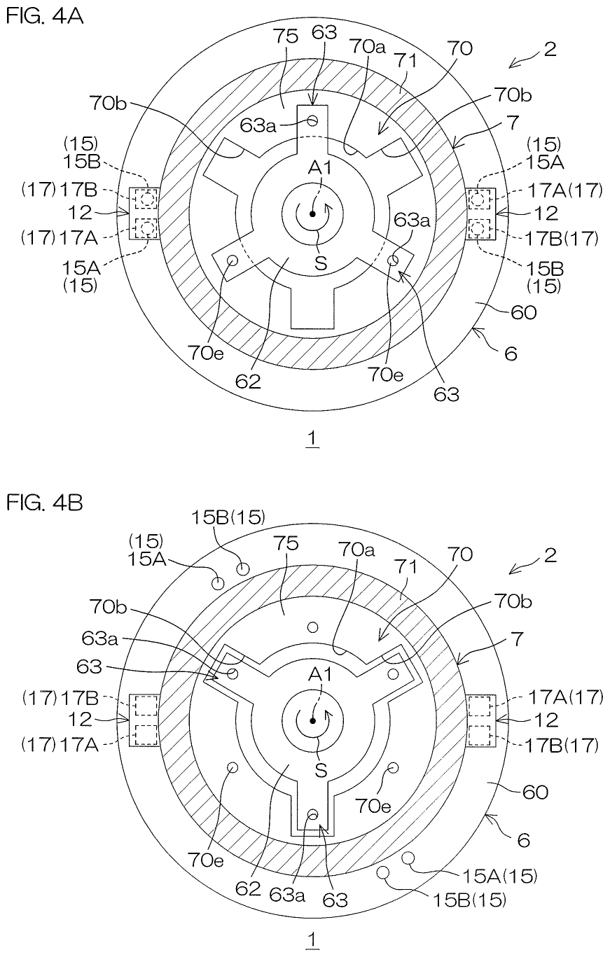

FIG. 4A and FIG. 4B are sectional views which is taken along line IV to IV in FIG. 2. In FIG. 4A and FIG. 4B, nozzles 30, 40, 50 and the nozzle housing member 35 are not shown in the drawings. In FIG. 4A and FIG. 4B, a relative rotation position of the facing member 6 is different. The relative rotation position of the facing member 6 is a position of the facing member 6 with respect to the supporting member 7 in the rotation direction S.

FIG. 4A is a drawing which shows a state where the relative rotation position of the facing member 6 is a supporting position. The supporting position is a position at which the facing member 6 can be supported by the supporting member 7. FIG. 4B is a drawing which shows a state where the relative rotation position of the facing member 6 is positioned at a removal position. The removal position is a position at which the facing member 6 can be removed from the supporting member 7 (can be attached thereto or detached therefrom).

The facing member supporting portion 70 supports the facing member 6 (the flange portion 63 thereof) from below (refer to FIG. 2 as well). A tubular portion through hole 70a through which the tubular portion 62 is inserted is formed at a central portion of the facing member supporting portion 70. A plurality of flange portion through holes 70b which are communicatively connected with the tubular portion through hole 70a and extend horizontally from the tubular portion through hole 70a are formed at the facing member supporting portion 70. The plurality of flange portion through holes 70b are kept at intervals from each other in the rotation direction S. The plurality of flange portion through holes 70b overlap the plurality of flange portions 63 in a plan view when the facing member 6 is positioned at the removal position. In detail, the flange portion 63 overlaps one by one with each of the flange portion through holes 70b. Therefore, the facing member 6 can be removed from the supporting member 7.

A positioning hole 63a which penetrates through the flange portion 63 in the vertical direction, are formed at each of the flange portions 63., A plurality of engaging protrusions 70e, each of which can be engaged with a positioning hole 63a of a corresponding flange portion 63, are formed at the facing member supporting portion 70. The corresponding engaging protrusion 70e is engaged with each of the positioning holes 63a, so that a position of the facing member 6 in the rotation direction S is positioned at the supporting position.

Each of the detecting units 12 optically detects a position of a corresponding portion to be detected 15 with respect to the detecting unit 12. The pair of detecting units 12 are disposed at the supporting member 7. The pair of detecting units 12 are spaced apart from each other in the rotation direction S. The pair of detecting units 12 are arranged, for example, at an interval of 180 degrees. The pair of detecting units 12 are mounted on an external surface of the detecting unit supporting portion 71 (from the outside in a rotation diameter direction of the substrate W).

The detecting unit 12 includes a pair of distance measurement sensors 17, each of which is different in measurement range. The distance measurement sensors 17 measure optically a distance between the detecting unit 12 and a portion to be detected 15 in the vertical direction. Thereby, the distance measurement sensors 17 detect a position of the portion to be detected 15 with respect to the detecting unit 12. If the upper surface 15a of the first protrusion 15A and that of the second protrusion 15B are reflection surfaces, the protrusions 15A, 15B can be detected with high sensitivity by the distance measurement sensors 17 (refer to FIG. 2 as well).

One of the distance measurement sensors 17 at each of the detecting units 12 is an upper position sensor 17A which measures a distance between the detecting unit 12 and the first protrusion 15A of the portion to be detected 15 when the supporting member 7 is positioned at the upper position. A distance between the detecting unit 12 and the first protrusion 15A (the upper surface 15a thereof) in the vertical direction when the supporting member 7 is positioned at the upper position is referred to as a first distance L1 (refer to FIG. 8A which will be described later).

The other of the distance measurement sensors 17 at each of the detecting units 12 is a lower position sensor 17B which measures a distance between the detecting unit 12 and the second protrusion 15B of the portion to be detected 15 when the supporting member 7 is positioned at the lower position. A distance between the detecting unit 12 and the second protrusion 15B (the upper surface 15a thereof) in the vertical direction when the supporting member 7 is positioned at the lower position is referred to as a second distance L2 (refer to FIG. 8C which will be described later).

As shown in FIG. 4A, when the relative rotation position of the facing member 6 is the supporting position, the upper position sensor 17A of each of the detecting units 12 overlaps a corresponding first protrusion 15A in a plan view. In other words, each of the first protrusions 15A faces a corresponding upper position sensor 17A in the vertical direction, and each of the first protrusions 15A is positioned directly below a corresponding upper position sensor 17A. In this state, each of the upper position sensors 17A is able to measure a distance between the upper surface 15a of the corresponding first protrusion 15A and the upper position sensor 17A.

Similarly, when the relative rotation position of the facing member 6 is the supporting position, the lower position sensor 17B of each of the detecting units 12 overlaps a corresponding second protrusion 15B in a plan view. In other words, each of the second protrusions 15B faces a corresponding lower position sensor 17B in the vertical direction, and each of the second protrusions 15B is positioned directly below a corresponding lower position sensor 17B. In this state, each of the lower position sensors 17B is able to measure a distance between the upper surface 15a of the corresponding second protrusion 15B and the lower position sensor 17B.

On the other hand, when the relative rotation position of the facing member 6 is at a position other than the supporting position (for example, the removal position shown in FIG. 4B), the upper position sensor 17A of each of the detecting units 12 deviates from the corresponding first protrusion 15A in the rotation direction S. Further, at this time, the lower position sensor 17B of each of the detecting units 12 deviates from the corresponding second protrusion 15B in the rotation direction S. Accordingly, the upper position sensor 17A is not able to measure a distance between the upper surface 15a of the corresponding first protrusion 15A and the upper position sensor 17A. The lower position sensor 17B is either not able to measure a distance between the upper surface 15a of the corresponding second protrusion 15B and the lower position sensor 17B concerned. Instead, when the relative rotation position of the facing member 6 is at a position other than the supporting position, each of the detecting units 12 is able to measure a distance between a part (the flat portion 60c), where the protrusions 15A, 15B are not disposed on the upper surface 60b of the facing portion 60, and the detecting unit 12.

With reference to FIG. 2, the facing member 6 includes a plurality of first engaging portions 81. The first engaging portion 81 extends downward from the facing surface 60a of the facing portion 60. The holding unit 24 includes a plurality of second engaging portions 85 which can be recess/protrusion engaged with the plurality of first engaging portions 81. The plurality of second engaging portions 85 extends upward from a peripheral edge portion of the upper surface of the spin base 21.

FIG. 5 is a sectional view which shows a vicinity of the first engaging portion 81 disposed at the facing member 6. FIG. 5 shows a state where engagement of the facing member 6 and the holding unit 24 is released. Each of the first engaging portions 81 includes a main body portion 82 which is made with a resin such as PEEK (polyether etherketone) resin, etc., and a permanent magnet 83. The main body portion 82 is fixed, with a part thereof being embedded into the facing portion 60, and a remaining part thereof protrudes downward from the facing surface 60a of the facing portion 60. A recessed portion 81a is formed at a lower end portion of the main body portion 82.

Each of the second engaging portions 85 is, for example, made with a metal. A main body portion 86 is fixed, with a part thereof being embedded into the spin base 21, and a remaining part protrudes upward from an upper surface of the spin base 21. A protruding portion 85a is formed at an upper end portion of the second engaging portion 85. The recessed portion 81a and the protruding portion 85a are fitted together, and the permanent magnet 83 of each of the first engaging portions 81 and the corresponding second engaging portion 85 are also attracted to each other, so that the facing member 6 and the holding unit 24 are engaged with each other (refer to FIG. 2).

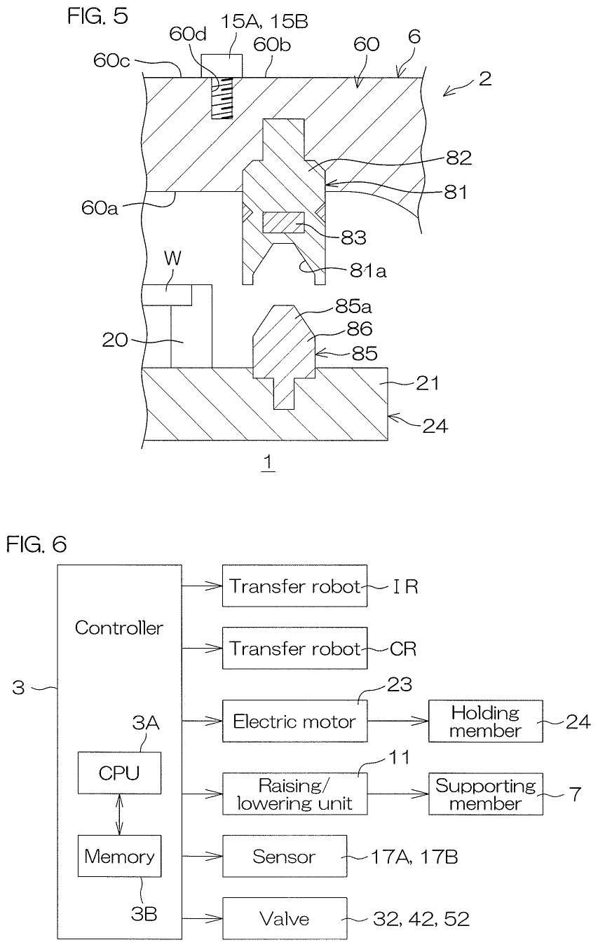

FIG. 6 is a block diagram for describing an electrical configuration of major portions in the substrate processing apparatus 1. The controller 3 is provided with a microcomputer and controls control targets provided in the substrate processing apparatus 1 in accordance with predetermined control programs. More specifically, the controller 3 includes a processor (CPU) 3A and a memory 3B in which the control programs are housed and is configured so as to execute various types of control for the substrate processing according to the control programs executed by the processor 3A. The controller 3 controls, in particular, motions of the transfer robots IR, CR, the electric motor 23, the raising/lowering unit 11, the sensors 17A, 17B and valves 32, 42, 52., etc.

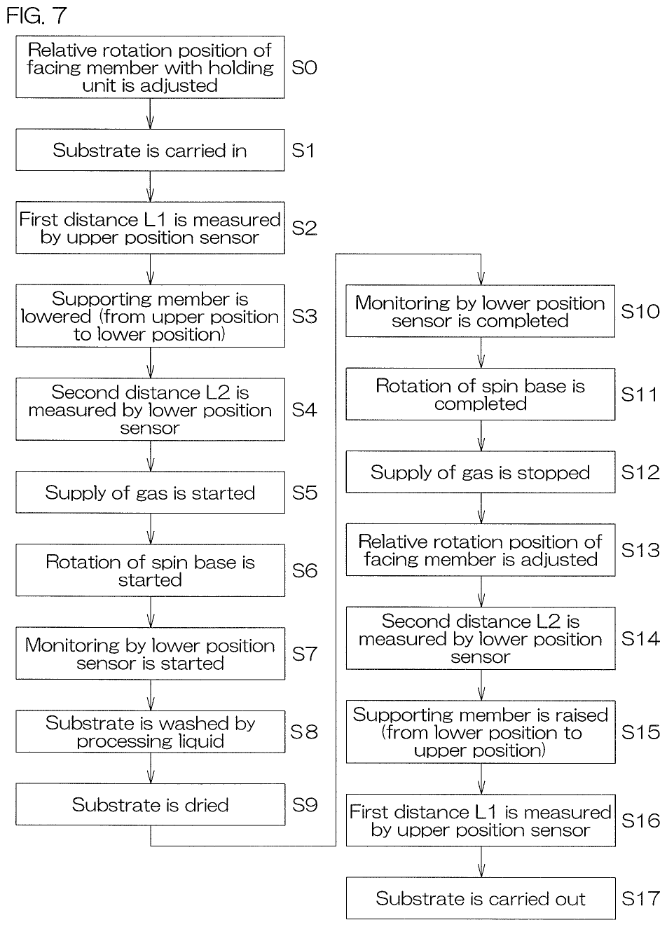

FIG. 7 is a flowchart for describing an example of the substrate processing by the substrate processing apparatus 1, showing the processing performed by mainly executing motion programs by the controller 3. FIG. 8A to FIG. 8F are each an illustrative sectional view for describing the substrate processing.

At first, before a substrate W is carried in the processing unit 2, the facing member 6 is supported by the supporting member 7 (supporting step). Next, a relative position of the facing member 6 with the holding unit 24 in the rotation direction S is adjusted such that the facing member 6 can be engaged with the holding unit 24 (Step S0: an engaging position adjusting step). In detail, the electric motor 23 adjusts a position of the holding unit 24 in the rotation direction S such that the first engaging portion 81 of the facing member 6 can overlap the second engaging portion 85 of the holding unit 24 in a plan view (refer to FIG. 2 as well).

Then, with reference to FIG. 1 as well, in the substrate processing by the substrate processing apparatus 1, the substrate W is carried in the processing unit 2 from the carrier C by the transfer robots IR, CR and transferred to the spin chuck 5 (Step S1: the substrate is carried in). Thereafter, the substrate W is held horizontally by the chuck pin 20 and kept at intervals above from the upper surface of the spin base 21, until being carried out by the transfer robot CR (substrate holding step).

Then, as shown in FIG. 8A, the upper position sensor 17A of each of the detecting units 12 measures the first distance L1 (Step S2: a first distance measurement step). The controller 3 confirms that the first distance L1 is in agreement with a predetermined first reference distance. Thereby, it is confirmed that the facing member 6 is supported by the supporting member 7 which is positioned at the upper position. If the first distance L1 is different from the first reference distance or when there is a large deviation between the first distance L1 and the first reference distance, the controller 3 may discontinue the substrate processing. Then, the raising/lowering unit 11 lowers the supporting member 7 positioned at the upper position toward the lower position (Step S3: a lowering step).

Then, as shown in FIG. 8B, the supporting member 7 passes through the engaging position before moving to the lower position. When the supporting member 7 reaches the engaging position, the facing member 6 and the holding unit 24 are engaged with each other by magnetic force. In detail, the first engaging portion 81 of the facing member 6 and the second engaging portion 85 of the holding unit 24 are recess/protrusion engaged with each other in a state of being attracted to each other by a magnetic force. Thereby, the facing member 6 is supported from below by the holding unit 24 of which the height position is fixed. Therefore, when the supporting member 7 is further lowered downward from the engaging position, the facing member 6 is released from the support by the supporting member 7. In detail, the facing member supporting portion 70 of the supporting member 7 retracts downward from the flange portion 63 of the facing member 6. Then, as shown in FIG. 8C, the supporting member 7 reaches the lower position.

When the supporting member 7 reaches the lower position, the lower position sensor 17B of each of the detecting units 12 measures the second distance L2 (Step S4: a second distance measurement step). Then, the controller 3 confirms that the second distance L2 is in agreement with a predetermined second reference distance. Thereby, it is confirmed that the facing member 6 is engaged with the holding unit 24 and positioned at a suitable height position. If the second distance L2 is different from the second reference distance or when there is a large deviation between the second distance L2 and the second reference distance, the controller 3 may discontinue the substrate processing.

In a state where the facing member 6 and the holding unit 24 are engaged with each other, the atmosphere inside a space 65 between the facing member 6 and the upper surface of the substrate W is blocked from an ambient atmosphere. In this state, a gas valve 52 is opened. Thereby, as shown in FIG. 8D, supply of nitrogen gas (N2 gas) to the space 65 is started (Step S5: a gas supplying step).

Since the facing member 6 and the holding unit 24 are engaged with each other, they can rotate integrally. The electric motor 23 starts to rotate the holding unit 24, thereby starting rotation of the facing member 6 (Step S6: a rotating step). On the other hand, the supporting member 7 is separated from both the holding unit 24 and the facing member 6 and, therefore, will not rotate. As a result, the facing member 6 rotates relatively in relation to the supporting member 7 during the rotating step.

In one example of the substrate processing, supply of nitrogen gas has been started before rotation of the facing member 6. Unlike the above-described substrate processing, rotation of the facing member 6 may be started earlier than supply of nitrogen gas.

Then, after start of the rotating step, the lower position sensors 17B of the pair of detecting units 12 start to detect a position of the portions to be detected 15 in relation to the detecting unit 12. When the flat portion 60c of the facing portion 60 passes through directly below the lower position sensor 17B, the lower position sensors 17B measure a distance between the detecting unit 12 and the flat portion 60c of the facing portion 60. When the plurality of protrusions 15A, 15B pass through directly below the lower position sensors 17B, the lower position sensors 17B measure a distance between the detecting unit 12 and the portion to be detected 15. Accordingly, when the plurality of protrusions 15A, 15B pass through directly below the lower position sensors 17B, measurement results change significantly. Thereby, the lower position sensors 17B are able to detect a distance (angle) between the portions to be detected 15 and also able to measure distances (heights D1, D2 of the protrusions 15A, 15B) from an upper surface of the facing portion 60 to upper ends of the portions to be detected 15. It is possible to monitor a distance (rotation angle) between the upper surface of the facing member 6 and the detecting unit 12 by referring to a timing when the portion to be detected 15 is detected in the rotation direction S and a rotational speed of the facing member 6.

As described above, during the rotation of the facing member 6, the lower position sensor 17B continuously measures a distance between the upper surface 60b of the facing portion 60 of the facing member 6 and the detecting unit 12, thereby monitoring a distance between the portions to be detected 15 in the rotation direction S and a distance from the flat portion 60c of the facing portion 60 to the upper end (upper surface 15a) of the portion to be detected 15 (Step S7: a monitoring step). Further, in the monitoring step, a distance between the detecting unit 12 and the portion to be detected 15 is measured by the lower position sensor 17B, thus making it possible to monitor a distance between the detecting unit 12 and the portion to be detected 15.

Then, as shown in FIG. 8E, the upper surface of the substrate W is washed (processed) with a processing liquid (Step S8: substrate washing step). In detail, in a state where the space 65 is filled with a gas such as nitrogen gas, the chemical liquid valve 32 is opened. Thereby, supply of a chemical liquid (for example, hydrofluoric acid) to the upper surface of the substrate W from the chemical liquid nozzle 30 is started (a chemical liquid supplying step). The supplied chemical liquid spreads across an entire upper surface of the substrate W due to a centrifugal force. Thereby, the upper surface of the substrate W is processed (washed) by the chemical liquid.

Then, after the upper surface of the substrate W has been processed for a fixed time by a chemical liquid, the chemical liquid valve 32 is closed. Instead, the rinse liquid valve 42 is opened. Thereby, supply of a rinse liquid (for example, DIW) to the upper surface of the substrate W from the rinse liquid nozzle 40 is started (a rinse liquid supplying step). The supplied rinse liquid spreads across an entire upper surface of the substrate W due to a centrifugal force. Thereby, the chemical liquid adhered on the upper surface of the substrate W is washed away. In the chemical liquid supplying step and the rinse liquid supplying step, the electric motor 23 rotates the substrate W at a low speed (for example, 800 rpm). The chemical liquid supplying step and the rinse liquid supplying step are included in a processing liquid supplying step in which the upper surface of the substrate W is processed by a processing liquid.

Thereafter, the rinse liquid valve 42 is closed. Then, as shown in FIG. 8F, the electric motor 23 rotates the substrate W at a high speed (for example, 3000 rpm). Thereby, a large centrifugal force is applied to a rinse liquid on the substrate W, by which the rinse liquid on the substrate W is spun off around the substrate W. In this way, the rinse liquid is removed from the substrate W to dry the substrate W (Step S9: a substrate drying step).

Then, after the elapse of a predetermined time from the start of rotation of the substrate W at a high speed, there is completed detection of the portion to be detected 15 by the lower position sensors 17B of the pair of detecting units 12 (Step S10). Further, the electric motor 23 stops rotation of the substrate W by the holding unit 24 (Step S11). Still further, the gas valve 52 is closed to stop supply of a gas from the gas nozzle 50 (Step S12).

Then, while the portion to be detected 15 is detected by the lower position sensor 17B of each of the detecting units 12 so that a relative rotation position of the facing member 6 will be positioned at the supporting position (the position shown in FIG. 4A), the facing member 6 is adjusted for the relative rotation position (Step S13: a rotation adjusting step). In other words, in the rotation adjusting step, the facing member 6 is adjusted for the relative rotation position such that the relative rotation position of the facing member 6 will not be positioned at a predetermined relative rotation position (the removal position shown in FIG. 4B). In detail, the electric motor 23 adjusts a position of the holding unit 24 in the rotation direction S such that the lower position sensor 17B of each of the detecting units 12 can overlap a corresponding protrusion 15A or 15B in a plan view.

Then, with reference to FIG. 8C, the lower position sensor 17B of each of the detecting units 12 measures again the second distance L2 (Step S14: a second distance measurement step). As with the second distance measurement step in Step S4, when the second distance L2 is different from a second reference distance or when a deviation between the second distance L2 and the second reference distance is large, the controller 3 may discontinue the substrate processing. Then, the raising/lowering unit 11 raises the supporting member 7 positioned at the lower position toward the upper position (Step S15: a raising step).

Then, with reference to FIG. 8B, the supporting member 7 passes through the engaging position before reaching the upper position. When the supporting member 7 reaches the engaging position, the supporting member 7 supports the facing member 6 from below. The supporting member 7 is raised further above from the engaging position and then lifts the facing member 6 against a magnetic force acting between the facing member 6 and the holding unit 24. Thereby, Recess/protrusion engagement of the first engaging portion 81 of the facing member 6 with the second engaging portion 85 of the holding unit 24 is released. Thereby, the facing member 6 is separated above from the holding unit 24 (the second engaging portion 85 thereof). Then, with reference to FIG. 8A, the supporting member 7 reaches the upper position. When the supporting member 7 reaches the upper position, the upper position sensor 17A of each of the detecting units 12 measures again the first distance L1 (Step S16: a first distance measurement step). As with the first distance measurement step in Step S2, when the first distance L1 is different from a first reference distance or when a deviation between the first distance L1 and the first reference distance is large, the controller 3 may discontinue the substrate processing.

Thereafter, the transfer robot CR enters into the processing unit 2, scoops up the processed substrate W from the spin chuck 5 and carries it out of the processing unit 2 (Step S17: substrate is carried out). The substrate W is transferred from the transfer robot CR to the transfer robot IR and housed in a carrier C by the transfer robot IR.

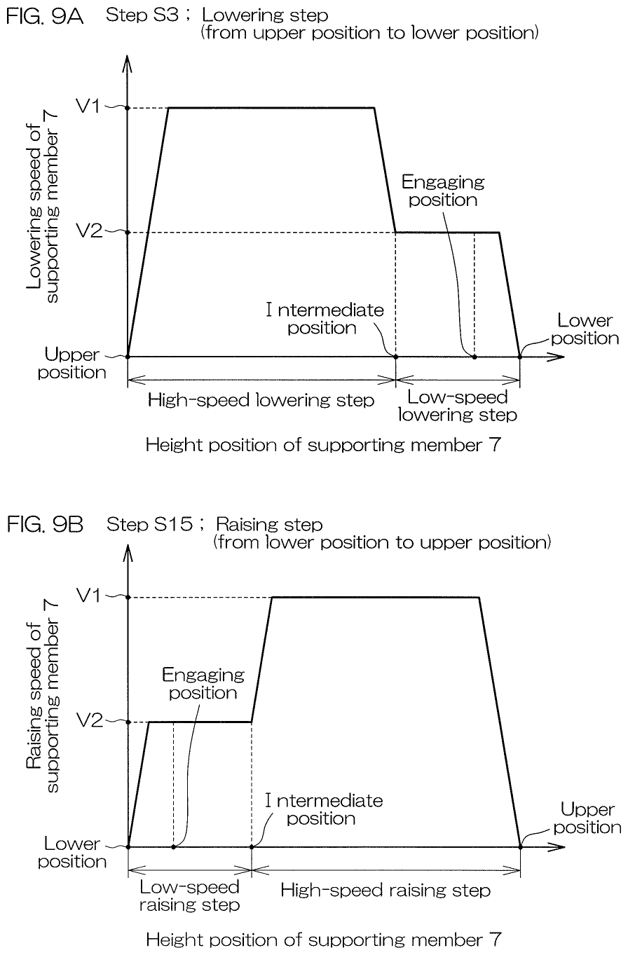

Next, a detailed description will be given of the lowering step of the substrate processing (Step S3 in FIG. 7) in the present preferred embodiment. FIG. 9A is a graph which shows a relationship between a height position of the supporting member 7 and a lowering speed of the facing member 6 in the lowering step. In FIG. 9A, the horizontal axis indicates a height position of the supporting member 7, and the vertical axis indicates a lowering speed of the supporting member 7. Further, the horizontal axis has an origin at the upper position (a left end of the horizontal axis) and is shown in the drawing so as to be further separated from the origin as it moves closer to the lower position.

As shown in FIG. 9A, the high-speed lowering step and the low-speed lowering step are executed in the lowering step. In detail, in the lowering step, at first, the raising/lowering unit 11 starts the lowering of the supporting member 7 which is positioned at the upper position. Then, the raising/lowering unit 11 accelerates the supporting member 7 until the lowering speed of the supporting member 7 reaches a first velocity V1. The raising/lowering unit 11 lowers the supporting member 7 at a fixed speed (first velocity V1) after a speed of the supporting member 7 has reached the first velocity V1. Thereafter, the raising/lowering unit 11 decelerates the lowering of the supporting member 7. Thereby, when the supporting member 7 reaches a predetermined intermediate position between the upper position and the engaging position, the speed of the supporting member 7 becomes a second velocity V2. The second velocity V2 is lower than the first velocity V1.

Thereafter, the raising/lowering unit 11 lowers the supporting member 7 at a fixed speed (second velocity V2) (a uniform speed lowering step). The supporting member 7 passes through the engaging position, while being lowered at a fixed speed. Thereafter, the supporting member 7 is decreased in speed and stopped at the lower position.

Here, the predetermined intermediate position is a magnetic force limit position in the present preferred embodiment. The magnetic force limit position is a position of the supporting member 7 when a distance between the first engaging portion 81 disposed at the facing member 6 and the second engaging portion 85 disposed at the holding unit 24 is a magnetic force limit distance. The magnetic force limit distance is a limit distance in which a magnetic force acts on the first engaging portion 81 and the second engaging portion 85. When the supporting member 7 is positioned between the intermediate position (magnetic force limit position) and the engaging position, a magnetic force is applied to the facing member 6. A distance between the magnetic force limit position and the lower position is, for example, 11 mm, and a distance between the magnetic force limit position and the upper position is, for example, 6.7 mm.

As described above, in the lowering step, there are executed the high-speed lowering step in which the supporting member 7 is lowered from the upper position to the intermediate position at a relatively high speed, and the low-speed lowering step in which it is lowered from the intermediate position to the lower position (engaging position) at a relatively low speed are executed. Then, in the low-speed lowering step, the uniform speed lowering step in which the supporting member 7 is lowered at a fixed speed (second velocity V2) is executed.

A speed of the supporting member 7 immediately after start of the lowering is lower than the second velocity V2. However, an average speed of the supporting member 7 in the high-speed lowering step is higher than an average speed of the supporting member 7 in the low-speed lowering step. Therefore, it can be said that from the upper position to the intermediate position, the supporting member 7 is lowered at a relatively high speed and from the intermediate position to the lower position, it is lowered at a relatively low speed.

Next, a detailed description will be given of the raising step of the substrate processing (Step S15 in FIG. 7) in the present preferred embodiment. FIG. 9B is a graph which shows a relationship between a height position of the supporting member 7 in the raising step and a raising speed of the facing member 6. In FIG. 9B, the horizontal axis indicates a height position of the supporting member 7 and the vertical axis indicates a raising speed of the supporting member 7. Further, the horizontal axis has an origin at the lower position (the left end of the horizontal axis) and shown in the drawing so as to be further separated from the origin as it moves closer to the upper position.

As shown in FIG. 9B, in the raising step, a low-speed raising step and a high-speed raising step are executed. In detail, in the raising step, at first, the raising/lowering unit 11 starts the raising of the supporting member 7 which is positioned at the lower position. Then, the raising/lowering unit 11 accelerates the supporting member 7 until a raising speed of the supporting member 7 becomes the second velocity V2. The raising/lowering unit 11 raises the supporting member 7 at a fixed speed (second velocity V2) after the speed of the supporting member 7 has reached the second velocity (a uniform speed raising step). The supporting member 7 passes through the engaging position while being raised at a fixed speed. Then, when the supporting member 7 reaches a predetermined intermediate position, the raising/lowering unit 11 accelerates the supporting member 7. The raising/lowering unit 11 raises the supporting member 7 at a fixed speed (first velocity V1) when the speed of the supporting member 7 reaches the first velocity V1. Thereafter, the supporting member 7 is decreased in speed and stopped at the upper position.

As described above, in the raising step, the low-speed raising step in which the supporting member 7 is raised from the lower position (engaging position) to the intermediate position at a relatively low speed and the high-speed raising step in which the supporting member 7 is raised from the intermediate position to the upper position at a relatively high speed are executed. Then, in the low-speed raising step, there is executed the uniform speed raising step in which the supporting member 7 is raised at a fixed speed (second velocity V2) is executed.

A speed of the supporting member 7 immediately before completion of the high-speed raising step is lower than the second velocity V2. However, an average speed of the supporting member 7 in the high-speed raising step is higher than an average speed of the supporting member 7 in the low-speed raising step. Therefore, from the lower position to the intermediate position, it can be said that the supporting member 7 is raised at a relatively low speed and from the intermediate position to the upper position, it is raised at a relatively high speed.

Next, a detailed description will be given of the monitoring step of the substrate processing (Step S7 in FIG. 7) in the present preferred embodiment. In the monitoring step, as described above, the pair of detecting units 12 monitor a distance between the portions to be detected 15 in the rotation direction S (a distance between the protrusions 15A and 15B) and a distance from the upper surface of the facing portion 60 to the upper end of the portion to be detected 15. In the present preferred embodiment, a similar measurement is to be made by both of the detecting units 12. Therefore, hereinafter, a description will be given of monitoring by one of the detecting units 12 in the pair of detecting units 12.

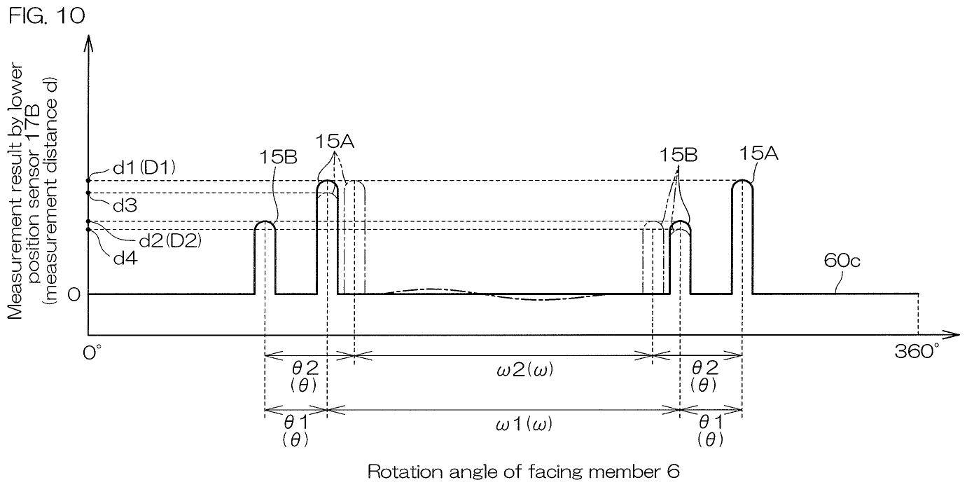

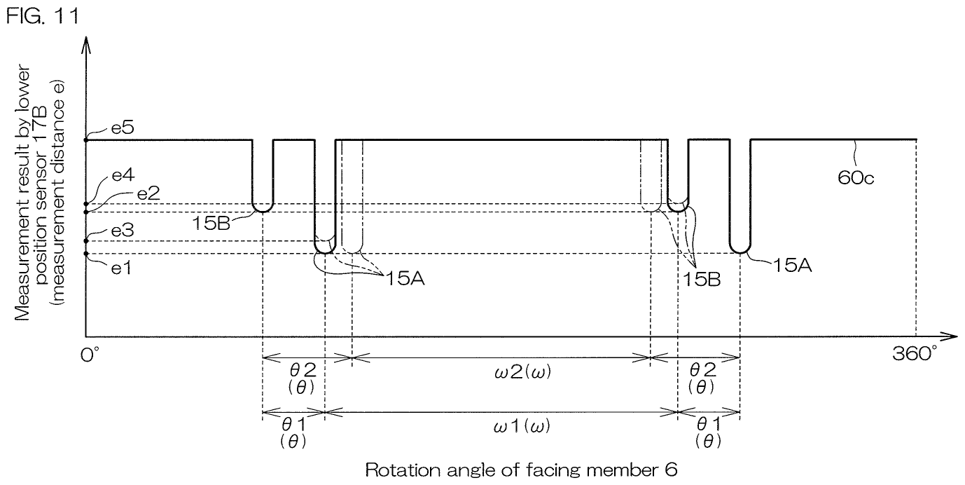

FIG. 10 is a graph which shows a relationship between a rotation angle of the facing member 6 during rotation and a distance between the facing member 6 and a measurement target. In FIG. 10, the horizontal axis indicates a rotation angle of the facing member 6, and the vertical axis indicates a measurement result of the lower position sensor 17B. In the vertical axis, a distance, obtained by subtracting a distance between the detecting unit 12 and the upper surface of the facing portion 60 of the facing member 6 from a distance from the lower position sensor 17B to the measurement target, is given as a measurement result by the lower position sensor 17B. That is, a distance from the upper surface of the facing portion 60 of the facing member 6 to the measurement target is given as a measurement result by the lower position sensor 17B. The distance from the upper surface of the facing member 6 to the measurement target is referred to as a measurement distance d. In the horizontal axis, a predetermined posture of the facing member 6 during rotation is set as 0° and a posture at which the facing member 6 rotates once from the posture in the rotation direction S is set as 360°.

A measurement result of an angle between a first protrusion 15A and a second protrusion 15B which is adjacent to the first protrusion 15A (that comes relatively close thereto in the rotation direction S) is given as a first measurement angle θ. A measurement result of an angle between a first protrusion 15A and a second protrusion 15B which is not adjacent to the first protrusion 15A (that is relatively separated in the rotation direction S) is given as a second measurement angle ω.

When the facing member 6 is deformed (for example, where undulation occurs on the upper surface 60b of the facing member 6) or when vibration occurs on the facing member 6 during rotation, the measurement distance d, the first measurement angle θ and the second measurement angle ω will be changed.

Thus, a measurement distance d, a first measurement angle θ and a second measurement angle ω in a state where the facing member 6 is not deformed are stored in advance at the controller 3. The state where the facing member 6 is not deformed is a state where the facing member 6 is not deformed from a state of the facing member 6 before the start of being used in the substrate processing apparatus 1. The state where the facing member 6 is not deformed is referred to as an initial state.

The first measurement angle θ in the initial state is given as an angle θ1, and the second measurement angle ω in the initial state is given as an angle ω1. In the initial state, the measurement distance d is to be zero excluding a case where the protrusions 15A, 15B pass through directly below the lower position sensors 17B. That is, in the initial state, the measurement distance d when the flat portion 60c passes through directly below the lower position sensor 17B is to be zero. In the initial state, the measurement distance d when the first protrusion 15A passes through directly below the lower position sensor 17B is given as a distance d1. The distance d1 is equal to a first height D1 from the flat portion 60c of the facing member 6 in a state of not being deformed to the upper surface 15a of the first protrusion 15A. In the initial state, the measurement distance d when the second protrusion 15B passes through directly below the lower position sensor 17B is given as a distance d2. The distance d2 is equal to a second height D2 from the flat portion 60c of the facing member 6 in a state of not being deformed to the upper surface 15a of the second protrusion 15B.

When a variation in measurement distance d, first measurement angle θ (angle θ1) or second measurement angle ω (angle ω1) in the initial state during the monitoring step exceeds a predetermined threshold, the substrate processing is discontinued due to occurrence of abnormalities. The threshold may be set in stages. Specifically, the threshold may be classified into a first threshold at which an alarm is given for informing detection of the deformation and a second threshold at which the substrate processing is stopped.

A description will be given of a mode of change in measurement distance d, first measurement angle θ or second measurement angle ω where the facing member 6 is deformed because of being used in the substrate processing apparatus 1.

The facing member 6 is deformed, by which, as shown by a double dotted & dashed line in FIG. 10, the first protrusion 15A and the second protrusion 15B may be changed in height. For example, when the facing member 6 is deformed such that the first protrusion 15A may be positioned below from a position of the first protrusion 15A in the initial state, the measurement distance d when the first protrusion 15A passes through directly below the lower position sensor 17B becomes a distance d3 which is smaller than the distance d1 (first height D1). Further, when the facing member 6 is deformed so that the second protrusion 15B will be positioned below from a position of the second protrusion 15B in the initial state, the measurement distance d when the second protrusion 15B passes through directly below the lower position sensor 17B becomes a distance d4 which is smaller than the distance d2 (second height D2).

Unlike an example shown in FIG. 10, the facing member 6 is assumed to be deformed such that the first protrusion 15A will be positioned above from a position of the first protrusion 15A in the initial state. At this time, the measurement distance d when the first protrusion 15A passes through directly below the lower position sensor 17B becomes larger than the first height D1. Similarly, unlike the example shown in FIG. 10, the facing member 6 is also assumed to be deformed such that the second protrusion 15B will be positioned above from a position of the second protrusion 15B in the initial state. At this time, the measurement distance d when the second protrusion 15B passes through directly below the lower position sensor 17B becomes larger than the second height D2.

Further, the facing member 6 is deformed, by which, as shown in the double dotted & dashed line in FIG. 10, a first protrusion 15A and a second protrusion 15B which is not adjacent to the first protrusion 15A (that is relatively separated in the rotation direction S) may come close to the rotation direction S.

A first protrusion 15A and a second protrusion 15B which is not adjacent to the first protrusion 15A come close to the rotation direction S, by which the first measurement angle θ becomes an angle θ2 which is larger than the first measurement angle (angle θ1) in the initial state, and the second measurement angle ω becomes an angle ω2 which is smaller than the second measurement angle (angle ω1) in the initial state.

Further, unlike the example shown in FIG. 10, the facing member 6 is deformed, by which a first protrusion 15A and a second protrusion 15B which is not adjacent to the first protrusion 15A (that is relatively separated in the rotation direction S) may be inclined so as to come close in the rotation direction S. In this case, a measurement distance d when the first protrusion 15A passes through directly below the lower position sensor 17B and a measurement distance d when the second protrusion 15B passes through directly below the lower position sensor 17B change. At the same time, the first measurement angle θ and the second measurement angle ω are also changed.

In a case where the facing member 6 is deformed, as shown by a single dot & dash line in FIG. 10, protrusions and recesses may occur at the flat portion 60c on the upper surface 60b of the facing portion 60. Accordingly, the measurement distance d when the flat portion 60c passes through directly below the lower position sensor 17B may become larger than zero or smaller than zero. The measurement distance d when the flat portion 60c passes through directly below the lower position sensor 17B is changed, thus making it possible to confirm an extent of deformation (extent of undulation) of the facing member 6 in its entirety and also a deterioration degree (settling degree) of the facing member 6.

In this way, in a state that the facing member 6 is engaged with the holding unit 24, a position of the portion to be detected 15 with respect to the detecting unit 12 is detected (monitored) by the detecting unit 12, thus making it possible to judge whether the facing member 6 is deformed or not.

Although in the present preferred embodiment, a similar measurement is to be made by both of the detecting units 12, a different measurement may be made by each of the detecting units 12. That is, a lower position sensor 17B of one of the detecting units 12 may measure a measurement distance d when the flat portion 60c passes through directly below the lower position sensor 17B, and a lower position sensor 17B of the other of the detecting units 12 may measure a measurement distance d when the portion to be detected 15 passes through directly below the lower position sensor 17B. In this case, the lower position sensor 17B of the other of the detecting units 12 detects the portion to be detected 15 which passes through directly below the lower position sensors 17B of the other of the detecting units 12, thereby measuring a first measurement angle θ and a second measurement angle ω.

Further, in the present preferred embodiment, the distance (measurement distance d) from the upper surface of the facing member 6 to a measurement target is given as a measurement result of the lower position sensor 17B (refer to FIG. 10). Unlike the present preferred embodiment, however, as shown in FIG. 11, the distance from the lower position sensor 17B to a measurement target may be given as a measurement result of the lower position sensor 17B. The distance from the lower position sensor 17B to a measurement target is given as a measurement distance e. FIG. 11 shows a measurement result in the initial state.

The measurement distance e when the first protrusion 15A passes through directly below the lower position sensor 17B in the initial state is given as a distance e1. The distance e1 is equal to a distance from the upper surface 15a of the first protrusion 15A to the lower position sensor 17B in a state where the facing member 6 is not deformed. The measurement distance e when the second protrusion 15B passes through directly below the lower position sensor 17B in the initial state is given as a distance e2. The distance e2 is equal to a distance from the upper surface 15a of the second protrusion 15B to the lower position sensor 17B in a state where the facing member 6 is not deformed. The measurement distance e when the flat portion 60c passes through directly below the lower position sensor 17B in the initial state is given as a distance e5. The distance e5 is equal to a distance from the flat portion 60c to the lower position sensor 17B in a state where the facing member 6 is not deformed. The measurement distance e when the flat portion 60c passes through directly below the lower position sensor 17B in the initial state may be out of a measurement range.

The measurement result shown in FIG. 11 will be changed, as with the measurement result shown in FIG. 10 due to deformation of the facing member 6. For example, when the facing member 6 is deformed such that the first protrusion 15A will be positioned below from a position of the first protrusion 15A in the initial state, the measurement distance e when the first protrusion 15A passes through directly below the lower position sensor 17B becomes a distance e3 which is larger than the distance e1. Further, when the facing member 6 is deformed so that the second protrusion 15B will be positioned below from a position of the second protrusion in the initial state, the measurement distance e when the second protrusion 15B passes through directly below the lower position sensor 17B becomes a distance e4 which is larger than the distance e2. A first protrusion 15A and a second protrusion 15B which is not adjacent to the first protrusion 15A come close in the rotation direction S, by which the first measurement angle θ becomes an angle θ2 which is larger than the first measurement angle (angle θ1) in the initial state, and the second measurement angle ω becomes an angle ω2 which is smaller than the second measurement angle (angle ω1) in the initial state.

In this way, even when the distance from the lower position sensor 17B to a measurement target is given as a measurement result, a position of the portion to be detected 15 with respect to the detecting unit 12 is detected (monitored) by the detecting unit 12, thus making it possible to judge whether the facing member 6 is deformed or not.

According to the present preferred embodiment, the substrate processing apparatus 1 includes a holding unit 24 which holds a substrate W horizontally, a facing member 6 which faces an upper surface of the substrate W from above and can be engaged with the holding unit 24, a supporting member 7 which supports the facing member 6, a raising/lowering unit 11 which raises and lowers the supporting member 7 between an upper position and an engaging position, and a detecting unit 12 which is disposed at the supporting member 7. The detecting unit 12 detects a position of a portion to be detected 15 disposed at the facing member 6 with respect to the detecting unit 12.

According to this configuration, the supporting member 7 is raised and lowered between an upper position which supports the facing member 6 and an engaging position at which the facing member 6 and the holding unit 24 are engaged with each other. The supporting member 7 is provided with the detecting unit 12 for detecting a position of the portion to be detected 15 which is disposed at the facing member 6. Therefore, in a state where the facing member 6 and the holding unit 24 are engaged with each other, a position of the portion to be detected 15 with respect to the detecting unit 12 can be detected by the detecting unit 12. Thereby, it is possible to judge whether the facing member 6 is positioned at a suitable position or not. That is, it is possible to judge whether the facing member 6 is properly engaged with the holding unit 24 during the substrate processing or not. It is also possible to judge whether the facing member 6 is deformed or not.

According to the present preferred embodiment, a pair of the detecting units 12 are disposed, with an equal interval kept in a circumferential direction (rotation direction S), around a vertical axis (rotation axis A1) passing through a central portion of the facing member 6. Therefore, it is possible to detect a position of the portion to be detected 15 with respect to the detecting unit 12 at two sites in the rotation direction S. Accordingly, it is possible to judge more accurately whether the facing member 6 is positioned at a suitable position or not. Thereby, it is possible to detect a state that the facing member 6 is inclined obliquely with respect to the holding unit 24. In other words, it is possible to judge whether the facing member 6 is kept in a horizontal posture or not.

According to the present preferred embodiment, the detecting unit 12 optically detects a position of the portion to be detected 15 with respect to the detecting unit 12. The portion to be detected 15 has a reflection surface (upper surface 15a) which will reflect light more easily compared to a part (flat portion 60c) of the facing member 6 other than the portion to be detected 15. Therefore, it is possible to improve the sensitivity at which the detecting unit 12 detects a position of the portion to be detected 15. Accordingly, it is possible to judge more accurately whether the facing member 6 is positioned at a suitable position or not.

According to the present preferred embodiment, the lowering step, in which the supporting member 7 is lowered from an upper position to a lower position, and the raising step, in which, after the lowering step, the supporting member 7 is raised from the lower position to the upper position, are executed.

According to the above-described configuration, the supporting member 7 supports the facing member 6 when the supporting member 7 is positioned at the upper position and is separated below from the facing member 6 when the supporting member 7 is positioned at the lower position. Therefore, when the supporting member 7 passes through an engaging position during the lowering step, the facing member 6 can be transferred from the supporting member 7 to the holding unit 24. Then, when the supporting member 7 passes through the engaging position during the raising step, the supporting member 7 can receive the facing member 6 from the holding unit 24. Accordingly, in such a configuration that the facing member 6 is transferred between the supporting member 7 and the holding unit 24, it is possible to judge whether or not the facing member 6 is positioned at a suitable position during the substrate processing.

According to the present preferred embodiment, the detecting unit 12 includes distance measurement sensors 12A, 12B which measure a distance between the detecting unit 12 and the portion to be detected 15, thereby detecting a position of the portion to be detected 15 with respect to the detecting unit 12. Then, before start of the lowering step, the first distance measurement step in which a distance between the detecting unit 12 and the portion to be detected 15 is measured by the detecting unit 12, and the second distance measurement step, in which, after completion of the lowering step, a distance between the detecting unit 12 and the portion to be detected 15 is measured by the detecting unit 12, are executed.

Therefore, a distance between the detecting unit 12 and the portion to be detected 15 is different between a state before start of the lowering step (a state that the supporting member 7 is positioned at the upper position) and a state after completion of the lowering step (a state that the supporting member 7 is positioned at the lower position). Accordingly, it is possible to judge whether the facing member 6 and the holding unit 24 have been normally engaged with each other or not, based on whether the amount of change in distance between the detecting unit and the portion to be detected is appropriate. It is, thereby, possible to judge more accurately whether or not the facing member 6 is positioned at a suitable position during the substrate processing.

In the present preferred embodiment, the portion to be detected 15 is disposed such that heights (first height D1 and second height D2) from the facing member 6 to the tip end (the upper surface 15a) of the portion to be detected 15 can be adjusted. Therefore, it is possible to adjust a height of the portion to be detected 15 in accordance with a measurement range of the distance measurement sensor 17. Accordingly, it is possible to judge more accurately whether or not the facing member 6 is positioned at a suitable position during the substrate processing.

According to the present preferred embodiment, the distance measurement sensor 17 includes an upper position sensor 17A which measures a distance between the detecting unit 12 and the portion to be detected 15 when the supporting member 7 is positioned at the upper position and a lower position sensor 17B which measures a distance between the detecting unit 12 and the portion to be detected 15 when the supporting member 7 is positioned at the lower position.

Therefore, a sensor which has a measurement range appropriate for measuring a distance (first distance L1) between the detecting unit 12 and the portion to be detected 15 when the supporting member 7 is positioned at the upper position can be used as the upper position sensor 17A. Further, a sensor which has a measurement range appropriate for measuring a distance (second distance L2) between the detecting unit 12 and the portion to be detected 15 when the supporting member 7 is positioned at the lower position can be used as the lower position sensor 17B. Accordingly, it is suppressed that a distance in which the supporting member 7 is separated in relation to the facing member 6 is restricted due to a measurement range of the sensor. There is also suppressed a decrease in detection accuracy of a distance between the detecting unit 12 and the portion to be detected 15. It is, thereby, possible to judge more accurately whether the facing member 6 is positioned at a suitable position or not during the substrate processing.

Here, in the lowering step and the raising step, it is conceivable that the supporting member 7 is lowered or raised at a fixed speed without changing a speed during each step. In a case where the supporting member 7 is lowered or raised at a fixed speed, the supporting member 7 is increased in lowering speed and raising speed, by which an impact which the facing member 6 receives is increased, although the number of substrates W which can be processed per unit time (throughput) is improved. Thereby, the facing member 6 is deformed or misaligned, so that the facing member 6 and the holding unit 24 may not engage well. In contrast, in a case where the supporting member 7 is lowered or raised at a fixed speed, the supporting member 7 is decreased in lowering speed and raising speed, by which the throughput may be reduced, although an impact which the facing member 6 receives is decreased.

According to the present preferred embodiment, in the lowering step, there are executed a high-speed lowering step in which the supporting member 7 is lowered at a relatively high speed from the upper position to the intermediate position and a low-speed lowering step in which the supporting member 7 is lowered at a relatively low speed from the intermediate position to the engaging position. Therefore, at a position separated above from the engaging position, the supporting member 7 is lowered at a relatively high speed and when the holding unit and the facing member are engaged with each other, the supporting member is lowered at a relatively low speed. Therefore, the lowering step can be completed in a short time. It is also possible to reduce an impact applied from the holding unit 24 to the facing member 6 when the facing member 6 and the holding unit 24 are engaged with each other. It is, therefore, possible to suppress the deformation of the facing member 6 and the positional deviation of the facing member 6 due to the impact while improving the throughput.

In the low-speed lowering step, the supporting member 7 is preferably lowered at a fixed speed. When the supporting member 7 is lowered at a fixed speed, a driving force of the electric motor 23 can be controlled such that a magnetic force acting on the facing member 6 can be balanced with a driving force of the electric motor 23. It is, thereby, possible to suppress vibration occurring at the facing member 6.

According to the present preferred embodiment, in the raising step, there are executed the low-speed raising step in which the supporting member 7 is raised at a relatively low speed from the engaging position to the intermediate position and the high-speed raising step in which the supporting member 7 is raised at a relatively high speed from the intermediate position to the upper position.

Therefore, when the facing member 6 is transferred from the holding unit 24 to the supporting member 7, the supporting member 7 is raised at a relatively low speed and at a position separated above from the engaging position, the supporting member 7 is raised at a relatively high speed. Accordingly, it is possible to complete the raising step in a short time and also possible to reduce an impact applied from the holding unit 24 to the facing member 6 when the facing member 6 and the holding unit 24 are engaged with each other. It is, thereby, possible to suppress the deformation of the facing member 6 and the positional deviation of the facing member 6 due to the impact while improving the throughput.

In the low-speed raising step, the supporting member is preferably raised at a fixed speed. In a case where the supporting member 7 is raised at a fixed speed, a driving force of the electric motor 23 can be controlled such that a magnetic force acting on the facing member 6 can be balanced with a driving force of the electric motor 23. It is, thereby, possible to suppress vibration occurring at the facing member 6.

According to the present preferred embodiment, a magnetic force acts on the facing member 6 when the supporting member 7 is positioned between the intermediate position and the engaging position. Therefore, the facing member 6 and the holding unit 24 can be easily engaged with each other by the magnetic force without using a complicated mechanism.

According to the present preferred embodiment, the substrate processing apparatus 1 further includes an electric motor 23 (rotating unit) which rotates the holding unit 24 around the rotation axis A1. There is executed a rotating step in which, in a state where the supporting member 7 is positioned at the lower position, the facing member 6 is rotated integrally with the holding unit 24 by the electric motor 23. Then, in parallel with the rotating step, there is executed a monitoring step in which positions of the plurality of portions to be detected 15 in relation to the detecting unit 12 are detected by the detecting unit 12, thereby monitoring a distance between the portions to be detected 15.

Therefore, in the rotating step, the facing member 6 and the holding unit 24 are engaged with each other and the supporting member 7 is separated below from the facing member 6, by which the facing member 6 is rotated integrally with the holding unit 24. Accordingly, in the rotating step, the facing member 6 rotates in relation to the supporting member 7. Therefore, in parallel with the rotating step, a position of the portion to be detected 15 with respect to the detecting unit 12 is detected by the detecting unit 12, thus making it possible to detect which position (angle) the portion to be detected 15 is positioned in the rotation direction S. Accordingly, it is possible to monitor a distance between the portions to be detected 15. The monitoring can be made continuously to detect deformation of the facing member 6 which has occurred during the rotation. It is possible to judge whether the facing member 6 is positioned at a suitable position or not by detecting the deformation during the rotation.

According to the present preferred embodiment, the facing member 6 can be attached to and detached from the supporting member 7 when the relative rotation position is a removal position (predetermined relative rotation position). Further, after completion of the rotating step and also before start of the raising step, there is executed a rotational position adjusting step in which the holding unit 24 is adjusted for a position in the rotation direction S such that the relative rotation position of the facing member 6 is not be a removal position. Accordingly, in such a configuration that the facing member 6 can be attached to and detached from the supporting member 7, it is possible to raise the supporting member 7 together with the facing member 6 after completion of the rotating step.

According to the present preferred embodiment, the detecting unit 12 is able to measure a distance between the detecting unit 12 and the upper surface 60b of the facing portion 60 of the facing member 6. In the monitoring step, there is also executed a step in which a distance between the detecting unit 12 and the upper surface 60b of the facing portion 60 is monitored. It is, thereby, possible to detect undulation on the upper surface of the facing member. Therefore, it is possible to detect more easily deformation of the facing member which has occurred during the rotation.

According to the present preferred embodiment, the plurality of portions to be detected 15 include a first protrusion 15A and a second protrusion 15B which are different from each other in height from the upper surface of the facing member 6.

A height from the upper surface of the facing member 6 to the first protrusion 15A and a height from the upper surface of the facing member 6 to the second protrusion 15B are different from each other. Therefore, a height position of the first protrusion 15A with respect to the detecting unit 12 and a height position of the second protrusion 15B with respect to the detecting unit 12 are also different from each other. Therefore, the detecting unit 12 is able to identify the first protrusion 15A and the second protrusion 15B. It is, thereby, possible to know more accurately a position of a deformed part of the facing member 6 in the rotation direction S.

The present invention shall not be limited to the embodiments described above and may be executed in other embodiments.

For example, in the above-described preferred embodiment, the first height D1 of the first protrusion 15A and the second height D2 of the second protrusion 15B are different from each other. Unlike the above-described preferred embodiment, the first height D1 and the second height D2 may be equal to each other.

Further, in the above-described preferred embodiment, a pair of the detecting units 12 is disposed. Unlike the above-described preferred embodiment, three or more detecting units 12 may be disposed at intervals in the rotation direction S. A larger number of the detecting units 12 makes it possible to judge more accurately whether the facing member 6 is positioned at a suitable position or not.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A substrate processing method comprising:
holding a substrate horizontally by a holding unit including a spin base and chucking pins;
supporting a facing member which faces an upper surface of the substrate from above by a supporting member including a wall to support the facing member;
measuring a first distance between a measurement target portion at the facing member and a distance measurement sensor disposed at the supporting member by the distance measurement sensor in a state where the supporting member is positioned at an upper position at which the supporting member supports the facing member such that the facing member is separated from the holding unit;
lowering the supporting member from the upper position to a lower position at which the supporting member is separated from the facing member in a state of being engaged with the holding unit, by way of an engaging position at which the holding unit and the facing member are engaged with each other; and
after completion of the lowering of the supporting member, measuring a second distance between the measurement target portion and the distance measurement sensor by the distance measurement sensor in a state where the supporting member is positioned at the lower position.

2. The substrate processing method according to claim 1, wherein
the lowering of the support member includes a high-speed lowering to lower the supporting member at a relatively high speed from the upper position to a predetermined intermediate position between the upper position and the engaging position, and a low-speed lowering to lower the supporting member at a relatively low speed from the predetermined intermediate position to the lower position.

3. The substrate processing method according to claim 2, wherein
the low-speed lowering includes a uniform speed lowering to lower the supporting member at a fixed speed.

4. The substrate processing method according to claim 1 further comprising:
raising the supporting member from the lower position to the upper position, wherein
the raising of the supporting member includes a low-speed raising to raise the supporting member at a relatively low speed from the lower position to a predetermined intermediate position between the upper position and the engaging position, and a high-speed raising to raise the supporting member at a relatively high speed from the predetermined intermediate position to the upper position.

5. The substrate processing method according to claim 4, wherein,
the low-speed raising of the supporting member includes a uniform speed raising to raise the supporting member at a fixed speed.

6. The substrate processing method according to claim 2, wherein
the holding unit and the facing member are configured to be engaged with each other by a magnetic force, and
the magnetic force is applied to the facing member when the supporting member is positioned between the predetermined intermediate position and the engaging position.

7. A substrate processing method comprising:
holding a substrate horizontally by a holding unit including a spin base and chucking pins;
supporting a facing member which faces an upper surface of the substrate by a supporting member including a wall to support the facing member;
lowering the supporting member from an upper position at which the supporting member supports the facing member such that the facing member is separated from the holding unit to a lower position which is a position lower than an engaging position at which the holding unit and the facing member are engaged with each other and at which the supporting member is separated from the facing member in a state of being engaged with the holding unit;
when the supporting member is positioned at the lower position, rotating the holding unit in a rotation direction around a predetermined rotation axis along a vertical direction; and
in parallel with the rotating of the substrate, detecting, by a detecting unit disposed at the supporting member, positions of a plurality of detection target portions which are disposed on an upper surface of the facing member at intervals in the rotation direction in relation to the detecting unit, thereby monitoring a distance between the target detection portions.

8. The substrate processing method according to claim 7, further comprising:
after completion of the rotating of the substrate, adjusting a rotational position of the holding unit in the rotation direction such that the facing member is not positioned at a predetermined relative rotation position at which the facing member is attachable to and detachable from the supporting member, and
after completion of the adjusting of the rotational position of the holding unit, raising the supporting member from the lower position to the upper position.

9. The substrate processing method according to claim 7, further comprising:
monitoring a distance between the detecting unit and the upper surface of the facing member.
